(19) United States
(12) Patent Application Publication
(10) Pub. No.: US 2013/0114332 A1
(43) Pub. Date: May 9, 2013

(54) REDUCING READ DISTURBS AND WRITE FAILS IN A DATA STORAGE CELL

(71) Applicants: Yves Thomas LAPLANCHE, Crolles (FR); Kenza Charafeddine, Grenoble (FR)

(72) Inventors: Yves Thomas LAPLANCHE, Crolles (FR); Kenza Charafeddine, Grenoble (FR)

(73) Assignee: ARM LIMITED, Cambridge (GB)

(21) Appl. No.: 13/288,293

(22) Filed: Nov. 3, 2011

(51) Int. Cl. G11C 11/40; G11C 7/00

(52) U.S. Cl. 365/154; 365/189.011

(57) ABSTRACT

A data storage cell having a data line configured to transmit a data value to and from the storage cell, a feedback loop configured to store the data value, a first access device to provide access between the data line and a first point in the feedback loop, a second access device to provide access between the data line and a second point in the feedback loop, the first access point being a less stable point in the feedback loop than the second access point such that a variation in a voltage at the first access point is more likely to disturb said data value stored in the feedback loop than a variation in voltage at the second access point.

### BACKGROUND OF THE INVENTION

1. Field of the Invention

The field of the invention relates to the field of data storage and in particular, to the storage and access of data in semiconductor memories.

2. Description of the Prior Art

With ever increasing demands to reduce both the size of devices and their power consumption, it is becoming increasingly challenging to design robust semiconductor memories such as SRAM. Each storage cell in an SRAM comprises a feedback loop for holding a data value. In order to write to the feedback loop and store a new value, the input data value must be able to switch the state stored by the feedback loop if required, while reading from the feedback loop should be performed without disturbing the values stored in any of the feedback loops.

SRAM bit cells are generally designed to be small and can conventionally be built from 6 transistors. One conventional way of making a cell easier to write to at lower voltages has been to make the pull down NMOS transistors connecting to VSS on either side of the feedback loop weaker. This can be done by changing the size of the transistors, however, where the size of the transistors is constrained, such as for example, in FinFET technologies a size change may not be possible. In such cases rather than changing the size of the transistor to make it weaker an additional NMOS transistor may be added in series with the other NMOS transistor thereby generating an 8 T cell. A drawback of this is an increase in area and in increase in read disturbs. As although the cell may be easier to write to, the cell is less stable and thus, read disturbs are more likely.

It would be desirable to be able to reduce write failures of a semiconductor memory without unduly increasing the read disturbs.

### SUMMARY OF THE INVENTION

A first aspect of the present invention provides a data storage cell comprising: a data line configured to transmit a data value to and from said storage cell; a feedback loop configured to store said data value; a first access device configured to provide access between said data line and a first point in said feedback loop; a second access device configured to provide access between said data line and a second point in said feedback loop; said first access point being a less stable point in said feedback loop than said second access point such that a variation in a voltage at said first access point is more likely to disturb said data value stored in said feedback loop than a variation in voltage at said second access point.

The present invention recognises that when accessing a feedback loop the point at which it is accessed may have an effect on its stability as some points in a feedback loop are more stable than others. Accessing a feedback loop at a less stable point will make it easier to change the data value stored and thus, easier to write. It will however, also make it more open to read disturbs. The present invention addresses these competing requirements by providing two access devices one connecting a data line to a less stable point and the other connecting the data line to a more stable point. In this way depending on whether a data value is to be written or read an appropriate access point can be selected by controlling the required access device and the storage cell can be accessed with reduced risk of either write failure or read disturb.

Although in some embodiments there may be a single data line that is connected to the storage cells in other embodiments, said data storage cell further comprises a complementary data line to transmit the inverse of said data value; and
a further first access device configured to provide access between said complementary data line and a complementary first access point on an opposing side of said feedback loop to said first access point;
a further second access device configured to provide access between said complementary data line and a complementary second access point on an opposing side of said feedback loop to said second access point;
said further first access point being a less stable point in said feedback loop than said further second access point such that a variation in a voltage at said further first access point is more likely to disturb said data value stored in said feedback loop than a variation in voltage at said further second access point.

In many storage cells it is found to be advantageous to have a data line and a complementary data line that are connected to either sides of the feedback loop of the storage cell. Such an arrangement makes it easier to read and write from the cell. In such cells there are further first and second access devices that provide access between the complementary data line are the feedback loop. The data line and the complementary data line are connected to opposite sides of the feedback loops via these access devices.

Although the data storage cell can take a number of forms, in some embodiments said data storage cell comprises SRAM cell, said feedback loop comprising at least six transistors arranged in two stacks, each stack having at least three transistors arranged in series between a high voltage line and a low voltage line, said first and second access points being arranged on one of said stacks on either side of a middle at least one of said at least three transistors.

SRAM cells are a convenient way of storing data and are often formed with feedback loops of four transistors. Slightly larger cells formed with feedback loops of six transistors are known, these loops have stacks of three transistors on either side of the loop. In such an arrangement, it is found to be advantageous to have the first and second access points on either side of a middle one of the three transistors. Adding an additional transistor to the conventional two transistors on either side of the feedback loop weakens the effect of the pull down transistor and thus, an access point located above the two pull down transistors is accessing an unstable part of the feedback loop and providing access to a data line at this point makes it easy to write to the cell but makes read disturbs more likely. An access point between the lower pull down transistors is at a very stable part of the feedback loop and a data value connected at this part of the loop makes it hard to write to the cell wire and similarly reading from this part of the loop runs a reduced risk of read disturbs. Although it may be advantageous to have a feedback loop of six transistors, feedback loops of more transistors are envisaged, with the access points being on either side of one or more of the middle transistors. Thus,. for example in an eight transistor feedback loop access, there would be stacks of four transistors on either side of the feedback loop and the access points would be on either side of one or two of the middle transistors in those stacks.

In the embodiments having a data line and a complementary data line connected to the feedback loop then the first and second access points are replicated on both of the at least three transistor stacks.

A second aspect of the present invention provides a data storage cell comprising:
a first data line configured to transmit a data value to and from said storage cell;
a further data line configured to transmit a further data value to and from said storage cell;
a feedback loop configured to store said data value;
a first access device configured to provide access between said data line and a first point in said feedback loop;
a second access device configured to provide access between said further data line and a second point in said feedback loop;
said first access point being a less stable point in said feedback loop than said second access point such that a variation in a voltage at said first access point is more likely to disturb said data value stored in said feedback loop than a variation in voltage at said second access point.

The provision of two access control devices to provide the improved read and write margins also allow for the device to be used as a dual port device such that one of the access devices accesses a first data line and the other access device accesses a further is data line. In this way two cells arranged in a same column in an array and that therefore share a data line will in this case be able to access one of two data lines and this allows one of the two cells to be read from and the other to be written to in the same cycle. It should be noted that in this embodiment the cell that is read from should be connected to the further data while that being written to should be connected to the first data line as these are connected to access devices that access the points with the required stability.

A third aspect of the present invention provides a memory comprising an array of data storage cells according to a first aspect of the present invention, said memory further comprising control circuitry responsive to data access requests to control at least one of said first and, second access devices to provide a connection between said data line and said feedback loop.

In some embodiments, said control circuitry is responsive to a read request to read said data value stored in one of said data storage cells by controlling said second access device to connect said data line to said second access point.

As noted previously the second access device provides access to a stable point in the feedback loop and therefore when reading from the cells it is advantageous that the read request controls the second access device.

In some embodiments, said control circuitry is further responsive to said read request to control said first access device to connect said data line to said first access point a predetermined time after having connected said data line to said second access point.

Accessing the storage cell through the second access device reduces the risk of read disturb. However, read disturb happens at the beginning of a read cycle and connecting the first access point to the data line at a later point in the read cycle can be done quite safely and can increase read speed while still providing a low risk of read disturb.

In some embodiments, said control circuitry is responsive to a write request to control said first access device that connects the data line to said first access point.

In order to be able to write to a storage cell the less stable access point should be accessed using the first access device. It should be noted that if the cells are in arrays where a write request will control all the first access devices in a row to connect their respective data lines to a first access point then read disturbs may occur in the other cells on the row that are not being written to. These are termed half selected cells.

In order to address this problem, in some embodiments said control circuitry is responsive to said write request to control said second access device to connect said data line to said second access point and after a predetermined time to control said first access device to connect said data line to said first access point.

As noted previously the probability of a read disturb is highest at the beginning of an access cycle where the data lines are holding their most charge. Thus, if read disturbs of the half selected cells are to be reduced, it may be advantageous to connect the second access device to the storage cell first and after a predetermined time connect the first access cell to the storage device. This will reduce the probability of a read disturb in the half selected cells but will increase the time period of the write request. Thus, in devices designed so that there are no half selected cells it is more advantageous simply to immediately connect the first access device.

In some embodiments, said control circuitry is responsive to a data access request to control said second access device to connect said data line to said second access point and after a predetermined time to control said first access device to connect said data line to said first access point.

Where the data storage cells are arranged so that there are half selected cells during a data access then using the second access device to connect the cells at the second access point to the data line and then connecting the first access point may be advantageous for both types of data access request, that is both reads and writes.

A fourth aspect of the present invention provides a memory comprising an array of data storage cells according to a second aspect of the present invention.

In some embodiments, said memory further comprises control circuitry responsive to a write request to load said data to said data line and control said first access device to connect said data line to said first access point and responsive to a read request to control said second access device to connect said further data line to said second access point.

Where data storage cells are used as dual port data storage cells connected to two data lines then it may be advantageous to connect the data line to the first access point in response to a write request and to use the further data line and the second access point in response to a read request.

In some embodiments, said memory further comprises a switch for connecting said data line to said further data line in response to a control signal indicating a single port mode of operation.

It may be advantageous to provide a switch to connect the two data lines such that the memory can be used in both single and dual port modes of operation. In this regard when used in a single port mode of operation then the control circuitry is responsive to a data access request to control said second access device to connect said further data line to said second access point and after a predetermined time to control said first access device to connect said data line to said first access point.

In this way a dual port memory can be used in single port mode in a way that reduces write failures and read disturbs where appropriate.

A fifth aspect of the present invention provides a method of accessing data stored in a data storage cell; said data storage cell comprising a data line configured to transmit a data value to and from said data storage cell, and a feedback loop configured to store said data value, said method comprising the steps of:
receiving a read request;
(i) controlling a second access device to provide access between said data line and a second point in said feedback loop; wherein
said second access point is a more stable point in said feedback loop than a first access point such that a variation in a voltage at said second access point is less likely to disturb said data value stored in said feedback loop than a variation in voltage at said first access point.

A sixth aspect of the present invention provides a means for storing data comprising:
a data line for transmitting a data value to and from said storage cell;
a feedback means for storing said data value;
a first access means for providing access between said data line and a first point in said feedback means;
a second access means for providing access between said data line and a second point in said feedback means;
said first access point being a less stable point in said feedback loop than said second access point such that a variation in a voltage at said first access point is more likely to disturb said data value stored in said feedback loop than a variation in voltage at said second access point.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically shows a data storage cell according to an embodiment of the present invention;

FIG. 2 schematically shows a data storage cell with a single data line according to an embodiment of the present invention;

FIG. 3a shows a data storage cell with a data line and a complementary data line according to an embodiment of the present invention;

FIG. 3b shows an alternative arrangement of the data storage cell of FIG. 3a;

FIG. 4 shows a dual port data storage cell according to an embodiment of the present invention;

FIG. 5 shows a memory comprising an array of storage cells according to an embodiment of the present invention;

FIG. 6 shows voltage levels during read and writes of selected and half selected cells;

FIG. 7 shows steps in a method of accessing a data storage cell according to an embodiment of the present invention; and

FIG. 8 shows a further method for accessing a data storage cell according to a further embodiment of the present invention.

### DESCRIPTION OF PREFERRED EMBODIMENTS

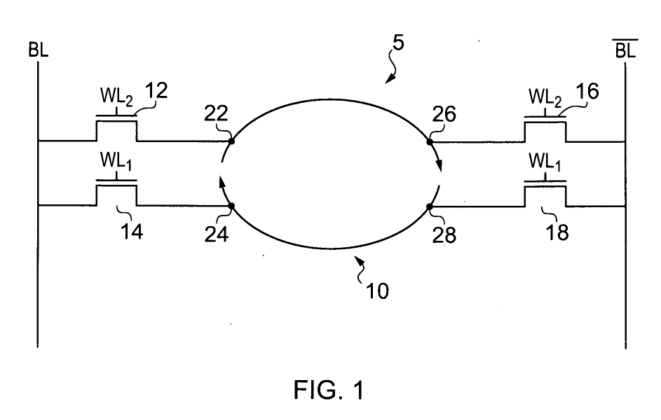

FIG. 1 shows a data storage cell 5 having a feedback loop 10 connected via two access devices 12 and 14 to a data line BL and connected via two other access devices 16 and 18 to a complementary data line B̅L̅.

Two of the access devices 12, 16 are controlled by a value on a second word line WL2. These devices connect the data line and complementary data line respectively to second access points 22 and 26 on the feedback loop 10. These second access points are stable points on the feedback loop so that changes in voltages at these points do not easily affect the value stored in the feedback loop. This makes these points very suitable as access points during a read but less suitable during a write.

There are further access devices 14 and 18 that are controlled by the signals on a first word line WL1. These are connected to access points 24 and 28 on the feedback loop. These access points are on a less stable point of the feedback loop 10 and thus, changes in voltages at these points more easily affect the value stored in the feedback loop and as such accessing the feedback loop at these points is convenient if a write is to be performed. However, if a read is to be performed these points are less good as it is more likely that a read disturb will occur.

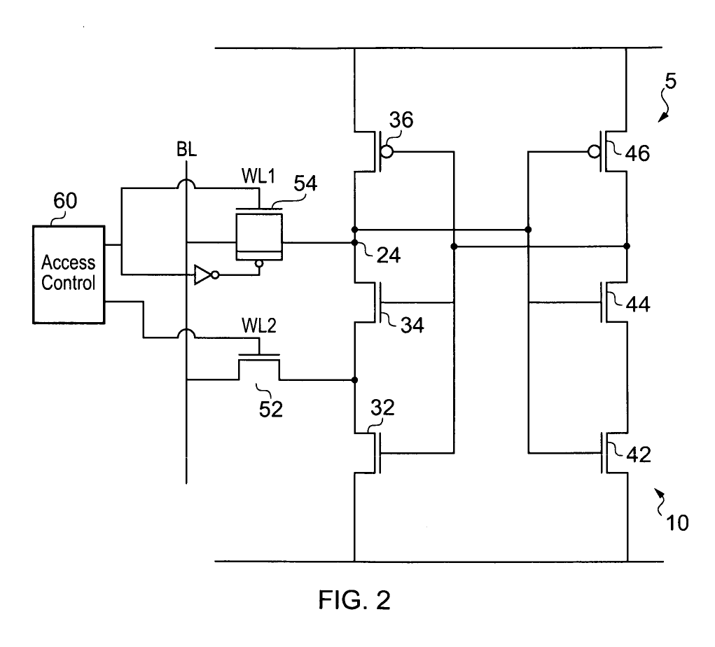

FIG. 2 shows an embodiment of a data storage cell 5 where there is only a single data line BL. In this case the feedback loop is a six transistor cell with two stacks of three transistors, the top transistor on the stack being. a PMOS transistor and the other two being NMOS transistors. In this case as in the former case there is a. first access device 54 that is controlled by WL1 that provides access to a first access point 24. This access point is at an unstable part of the feedback loop and changes in voltages here affect the value stored. This is because the stack of two NMOS transistors 32 and 34 are weak and are easily pulled down changing the value stored. In this embodiment the access device 54 is a transmission gate.

There is a further access device in the form of a transistor 52 that is controlled by a second word line WL2. Access control circuitry 60 provides signals to the word lines that control access to the feedback loop. Thus, in this embodiment if a write is requested the first access device 54 is used and if a read is requested the second access device 52 is used.

If a faster read is required it may be desirable to use both access devices during the read. This is acceptable if access device 52 is switched on first so that some charge sharing occurs at the beginning of the cycle when the stable portion of the feedback loop is accessed and then later the less stable part of the feedback loop is connected at which point it is much less likely that any undesirable changing of data value will occur.

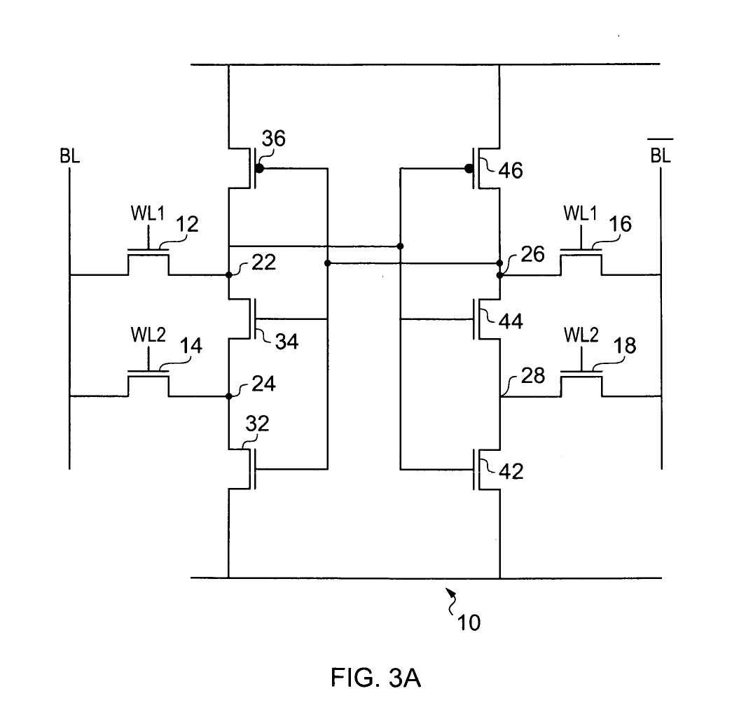

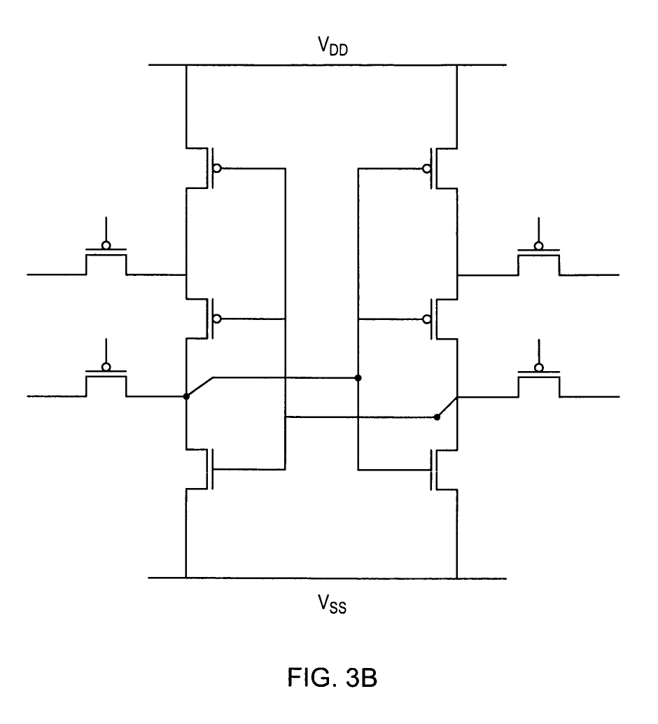

FIG. 3a shows a data storage cell with a data line BL and a complementary data line B̅L̅ according to an embodiment of the present invention. This data storage cell has a first set of access devices 12 and 16 that are controlled by a first word line WL1 and a second set of access devices 14 and 18 that are controlled by a second word line WL2. Each set of access devices provide access between respective sides of the feedback loop 10 and the data line BL or the complementary data line B̅L̅.

The feedback loop 10 is comprised of two stacks of transistors, each stack having a PMOS and two NMOS transistors. The first access device is located between the PMOS transistors 36, 46 and the top NMOS transistors 34, 44 while the second access point is located between the middle NMOS transistors 34, 44 and the lower NMOS transistors 32 and 42. As noted previously the second access point is the more stable access point and is therefore preferred for reads while the first access point 22 and 26 is preferred for writes.

FIG. 3b shows an equivalent storage cell to FIG. 3a but with PMOS and NMOS devices reversed.

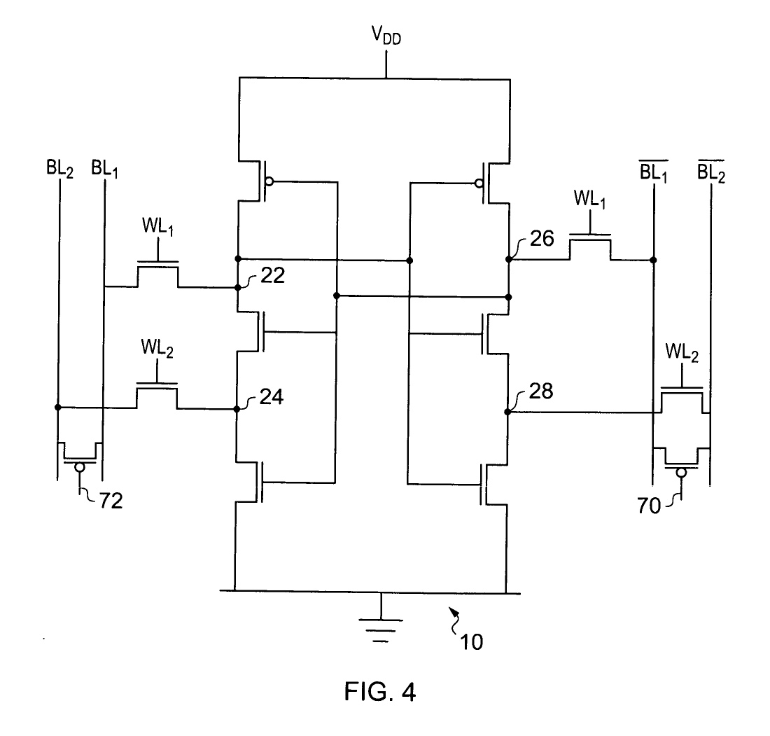

FIG. 4 shows an alternative dual port embodiment. As the storage cells of embodiments of the present invention have two access devices to access two access points in some embodiments these are not connected to a same data line but are rather connected to two different data lines BL1, BL2. This allows storage cells that are located in the same column in an array and that therefore access the same data line to have one cell read during one cycle and another written during the same cycle using different data lines. It should be noted that the advantageous features associated with accessing the storage cell of previous embodiments of the present invention may not always be achieved in this embodiment. In particular, accessing the feedback loop 10 via the second access point 24 and 28 is fine if a read is required but may cause a write failure if a write is tried. Similarly accessing the storage cell via access points 22 and 26 is good for a write but less good if a read is required.

For this reason, control circuitry associated with such a storage cell will try to provide data to be written on the first data line BL1 and B̅L̅1 and to read data via the second data lines BL2 and B̅L̅2.

In some embodiments, there is an additional switch 70 and 72 between the two data lines and the two complementary data lines and this can be connected if the device is to operate in single port mode. If this is the case then the same data is seen on both data lines and data can be read from and written to the cell using the required access port to reduce the risks of read disturb and write failure as for the previous embodiments.

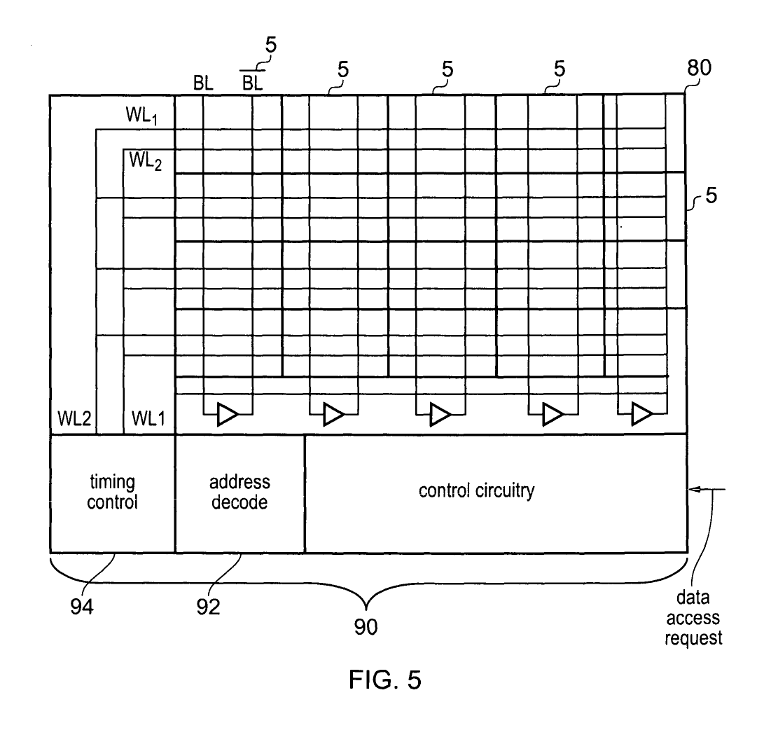

FIG. 5 shows an SRAM memory 80 according to an embodiment of the present invention. The SRAM memory 80 comprises an array of storage cells 5 each having a data line BL and a complementary data line B̅L̅ and a first word line WL1 and a second word line WL2. The memory 80 has control circuitry 90 that includes an address decoder 92 and timing control 94.

The control circuitry will receive a data access request and will determine using the address decoder 92 which row and column the required storage cell 5 is located in. If the data access request is a write it will then load the data value onto the data lines for that column and will activate the required word lines. It will do this by activating the second word line WL2 first and then using timing control circuitry 94 after a short delay it will activate the first word line WL1. The data on the data line will then be written to the required cell. It will use the timing control in this way to prevent a read disturb occurring on the half selected cells. Thus, rather than simply activating the first word line WL1 and writing the data to the cell it activates the second word line WL2 first which allows some charge sharing to occur between the half selected cells and the data lines before the first word line WL1 provides access to the less stable part of the feedback loop within the half selected storage cells.

In some embodiments, where the memory is set up such that there are no half selected cells in a row then in response to a write access request the first word line will be fired immediately and the write will proceed more quickly.

If the data access request is a reed request then again the address decoder determines the storage cell 5 to be accessed the data line and complementary data line of the selected column are precharged and then the word lines of the selected row are activated. First the second word line WL2 is activated and this provides the data lines with access to the required cell at a stable point in the cell. This helps avoid the data value stored in the cell being disturbed by the charge on the data lines. After a predetermined delay timing control circuitry 94 will activate the first word line WL1 and the less stable part of the feedback loop will be connected to the data lines. This will increase the speed of the read.

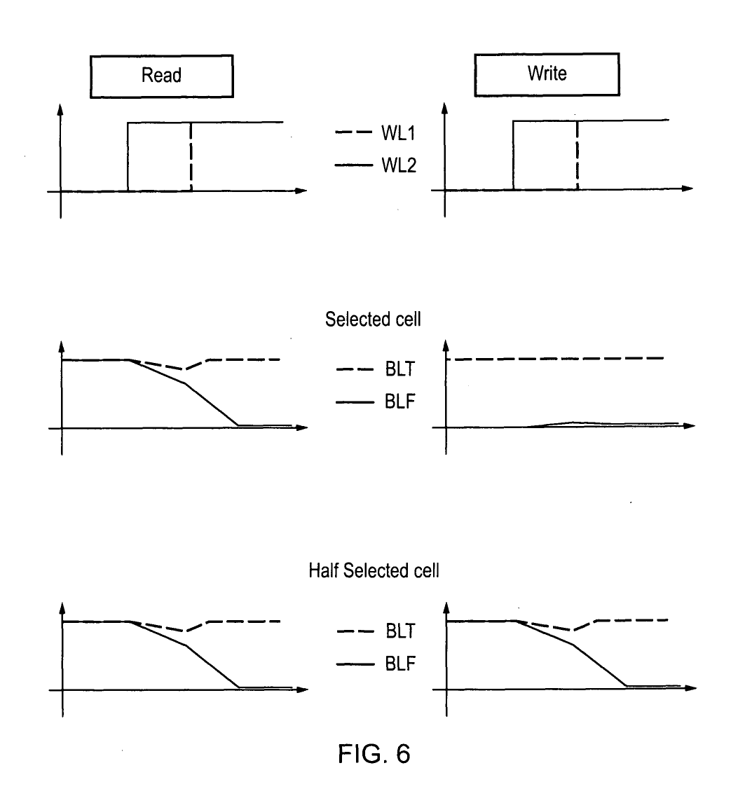

FIG. 6 shows the timings of the activations of the word line 1 and word line 2 during a read and write cycle and how this affects the voltage level on the bit line and complementary bit line. In this regard in this diagram the bit line is shown as BLT and the complementary bit line as BLF.

Thus, for a read cycle both the bit line and complementary bit line are charged and once the second word line WL2 is fired the voltage level on the complementary bit line starts to fall toward 0 and the voltage on the true bit BLT also starts to fall slightly. Then when the first word line is activated the fall in voltage level of the complementary bit line increases and the cells stabilise and the voltage level at the bit line return to one. Similar voltage changes occur on both the selected and half selected cells.

During the write cycle if a 1 is to be written then initially there is a 1 on the bit line and a 0 on the complementary bit line. When the second word line WL2 is fired the cell starts to share charge with charge from the complementary bit line and the voltage on the complementary bit line starts to fall. Then when the first word line is fired the rate of fall increases in the half selected cell and the voltage drops to 0 while the bit line remains at 1. In the selected cell there is only a slight wobble on the complementary bit line and otherwise the bit line and complementary bit line stay with their 1 and 0 value.

In summary during the read process the selected cells and half selected cells have the same behaviour. During a write the selected cell cannot be written as long as WL1 is not high. Once WL1 is high the first access device opens and the write proceeds quickly. The half selected cells simply perform a read action which refreshes the data currently stored in the cell.

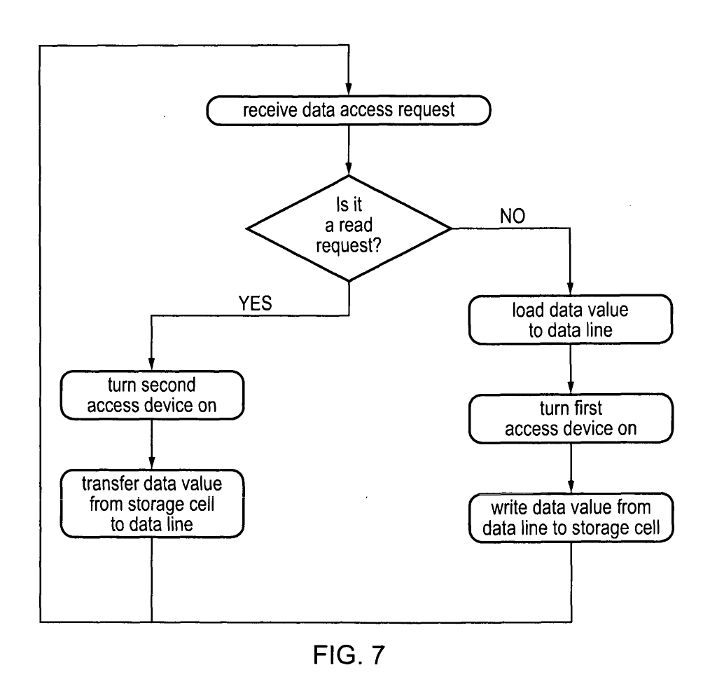

FIG. 7 illustrates a flow diagram showing a method where the memory is arranged such that there are no half selected cells. In this case in response to a data access request it is determine whether it is a read request, if it is the second access devices turns on and a data value is transferred from the storage cell to the data line. It should be noted that if an improved read access time is required the first access device can be turned on a short time after the second access device.

If it is not a read request than it is a write request and the data value is loaded onto the data line and then the first access devices is turned on and the data value is written for the data line to the storage cells.

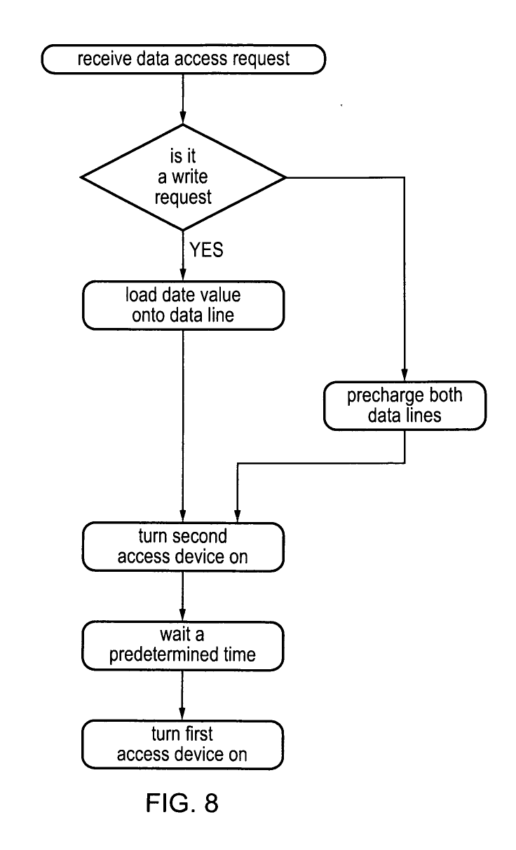

FIG. 8 shows an alternative method where the memory is arranged such that there are half selected cells in that a word line will turn on the access devices in all of the rows.

Thus, in this embodiment when a data access request is received it is determined if it is a write request and if it is the data value is loaded onto the data line if it is not both data line and complementary data line are precharged then the second access device is turned on, the system waits for a predetermined time and then turns the first access device on. Controlling the timing of the access devices in this way improves the read margins and reduces the risk of disturbing the values stored in half selected cells during the write.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims. For example, various combinations of the features of the following dependent claims could be made with the features of the independent claims without departing from the scope of the present invention.

We claim:

1. A data storage cell comprising:
a data line configured to transmit a data value to and from said storage cell;
a feedback loop configured to store said data value;
a first access device configured to provide access between said data line and a first point in said feedback loop;
a second access device configured to provide access between said data line and a second point in said feedback loop;
said first access point being a less stable point in said feedback loop than said second access point such that a variation in a voltage at said first access point is more likely to disturb said data value stored in said feedback loop than a variation in voltage at said second access point.

2. A data storage cell according to claim 1, said data storage cell further comprising:
a complementary data line to transmit the inverse of said data value; and
a further first access device configured to provide access between said complementary data line and a complementary first access point on an opposing side of said feedback loop to said first access point;
a further second access device configured to provide access between said complementary data line and a complementary second access point on an opposing side of said feedback loop to said second access point;
said further first access point being a less stable point in said feedback loop than said further second access point such that a variation in a voltage at said further first access point is more likely to disturb said data value stored in said feedback loop than a variation in voltage at said further second access point.

3. A data storage cell according to claim 1, said data storage cell comprising an SRAM cell, said feedback loop comprising at least six transistors arranged in two stacks, each stack having at least three transistors arranged in series between a high voltage line and a low voltage line, said first and second access points being arranged on one of said stacks on either side of a middle at least one of said at least three transistors.

4. A data storage cell according to claim 2, said data storage cell comprising an SRAM cell, said feedback loop comprising at least six transistors, each side of said feedback loop having at least three transistors arranged in series between a high voltage line and a low voltage line, said first and second access points being arranged on either side of a middle at least one of said at least three transistors on one side of said feedback loop and said further first and said further second access points being arranged on either side of a middle at least one of said at least three transistors on the other stack on the other side of said feedback loop.

5. A data storage cell comprising:
a first data line configured to transmit a data value to and from said storage cell;
a further data line configured to transmit a further data value to and from said storage cell;
a feedback loop configured to store said data value;
a first access device configured to provide access between said data line and a first point in said feedback loop;
a second access device configured to provide access between said further data line and a second point in said feedback loop;
said first access point being a less stable point in said feedback loop than said second access point such that a variation in a voltage at said first access point is more likely to disturb said data value stored in said feedback loop than a variation in voltage at said second access point.

6. A memory comprising an array of data storage cells according to claim 1, said memory further comprising control circuitry responsive to data access requests to control at least one of said first and second access devices to provide a connection between said data line and said feedback loop.

7. A memory according to claim 6, wherein said control circuitry is responsive to a read request to read said data value stored in one of said data storage cells by controlling said second access device to connect said data line to said second access point.

8. A memory according to claim 7, said control circuitry being further responsive to said read request to control said first access device to connect said data line to said first access point a predetermined time after having connected said data line to said second access point.

9. A memory according to claim 6, said control circuitry being responsive to a write request to control said first access device to connect said data line to said first access point.

10. A memory according to claim 9, said control circuitry being responsive to said write request to control said second access device to connect said data line to said second access point and after a predetermined time to control said first access device to connect said data line to said first access point.

11. A memory according to claim 6, said control circuitry being responsive to a data access request to control said second access device to connect said data line to said second access point and after a predetermined time to control said first access device to connect said data line to said first access point.

12. A memory comprising an array of data storage cells according to claim 5.

13. A memory according to claim 12, said memory further comprising control circuitry responsive to a write request to load said data to said data line and control said first access device to connect said data line to said first access point and responsive to a read request to control said second access device to connect said further data line to said second access point.

14. A memory according to claim 12, said memory further comprising a switch for connecting said data line to said further data line in response to a control signal indicating a single port mode of operation.

15. A memory according to claim 14, wherein in response to said memory operating in said single port mode of operation, said control circuitry is responsive to a data access request to control said second access device to connect said further data line to said second access point and after a predetermined time to control said first access device to connect said data line to said first access point.

16. A method of accessing data stored in a data storage cell; said data storage cell comprising a data line configured to transmit a data value to and from said data storage cell, and a feedback loop configured to store said data value, said method comprising the steps of:
receiving a read request;
(i) controlling a second access device to provide access between said data line and a second point in said feedback loop; wherein
said second access point is a more stable point in said feedback loop than a first access point such that a variation in a voltage at said second access point is less likely to disturb said data value stored in said feedback loop than a variation in voltage at said first access point.

17. A method according to claim 16, comprising a further step of
(ii) after said step of controlling said second access device, waiting a predetermined time and then controlling said first access device to provide access between said data line and a first access point in said feedback loop.

18. A method according to claim 16, comprising:
receiving a write request;
loading a data value of said write request onto said data line; and
performing step (ii).

19. A method according to claim 17, comprising a further step of performing step(i) prior to performing step (ii) and waiting a predetermined time between said two steps.

20. A means for storing data comprising:
a data line for transmitting a data value to and from said storage cell;
a feedback means for storing said data value;
a first access means for providing access between said data line and a first point in said feedback means;
a second access means for providing access between said data line and a second point in said feedback means;
said first access point being a less stable point in said feedback loop than said second access point such that a variation in a voltage at said first access point is more likely to disturb said data value stored in said feedback loop than a variation in voltage at said second access point.
